(19) United States
(12) Patent Application Publication
(10) Pub. No.: US 2024/0429314 A1
(43) Pub. Date: Dec. 26, 2024

(54) Implantation for Isolated Channel Structures in Group III-Nitride Semiconductor Devices

(71) Applicant: Wolfspeed, Inc., Durham, NC (US)

(72) Inventors: Kyle Bothe, Cary, NC (US); Michael Lee Schuette, Sunbury, OH (US); James Scott Tweedie, Raleigh, NC (US); Scott Sheppard, Chapel Hill, NC (US)

(21) Appl. No.: 18/340,471

(22) Filed: Jun. 23, 2023

(51) Int. Cl. H01L 29/778; H01L 29/16; H01L 29/20; H01L 29/40; H01L 29/417; H01L 29/66

(52) U.S. Cl. CPC H01L 29/7786; H01L 29/1608; H01L 29/2003; H01L 29/402; H01L 29/41766; H01L 29/66462

(57) ABSTRACT

Semiconductor devices are provided. In one example, a semiconductor device includes a Group III-nitride semiconductor structure. The semiconductor device includes a first contact on the Group III-nitride semiconductor structure. The semiconductor device includes a second contact on the Group III-nitride semiconductor structure. The second contact is spaced apart from the first contact. The Group III-nitride semiconductor structure includes a plurality of channel structures extending in a length direction between the first contact and the second contact. The semiconductor device includes an isolation implant region extending along at least a portion of a length of at least one of the plurality of channel structures. The isolation implant region comprises implanted dopants.

### FIELD

The present disclosure relates generally to semiconductor devices.

### BACKGROUND

Power semiconductor devices are widely used to carry large currents, support high voltages and/or operate at high frequencies such as radio frequencies. A wide variety of power semiconductor devices are available for different applications including, for example, power switching devices and power amplifiers. Many power semiconductor devices are implemented using various types of field effect transistors (FETs) devices including MOSFETs (metal-oxide semiconductor field-effect transistors), DMOS (double-diffused metal-oxide semiconductor) transistors, HEMTs (high electron mobility transistors), MESFETs (metal-semiconductor field-effect transistors), LDMOS (laterally diffused metal-oxide semiconductor) transistors, etc.

Power semiconductor devices may be fabricated from wide bandgap semiconductor materials (e.g., having a bandgap greater than 1.40 eV). For example, power HEMTs may be fabricated from gallium nitride (GaN) or other Group III nitride-based material systems that are formed, for instance, on a silicon carbide (SiC) substrate or other substrate. As used herein, the term “Group III nitride” refers to those semiconducting compounds formed between nitrogen and the elements in Group III of the periodic table, usually aluminum (Al), gallium (Ga), and/or indium (In). These compounds have empirical formulas in which one mole of nitrogen is combined with a total of one mole of the Group III elements. For high power, high temperature, and/or high frequency applications, devices formed in wide bandgap semiconductor materials such as silicon carbide (e.g., 2.996 eV bandgap for alpha silicon carbide at room temperature) and the Group III-nitrides (e.g., 3.36 eV bandgap for gallium nitride at room temperature) may provide higher electric field breakdown strengths and higher electron saturation velocities as compared to gallium arsenide (GaAs) and silicon (Si) based devices.

### SUMMARY

Aspects and advantages of embodiments of the present disclosure will be set forth in part in the following description, or may be learned from the description, or may be learned through practice of the embodiments.

One example aspect of the present disclosure is directed to a semiconductor device. The semiconductor device includes a Group III-nitride semiconductor structure. The semiconductor device includes a first contact on the Group III-nitride semiconductor structure. The semiconductor device includes a second contact on the Group III-nitride semiconductor structure. The second contact is spaced apart from the first contact. The Group III-nitride semiconductor structure includes a plurality of channel structures extending in a length direction between the first contact and the second contact. The semiconductor device includes an isolation implant region extending along at least a portion of a length of at least one of the plurality of channel structures. The isolation implant region comprises implanted dopants.

Another example aspect of the present disclosure is directed to a transistor device. The transistor device includes a substrate. The transistor device includes a Group III-nitride semiconductor structure on the substrate. The Group III-nitride semiconductor structure includes a first channel structure and a second channel structure that is electrically isolated from the first channel structure. The transistor device includes a source contact on the Group III-nitride semiconductor structure. The transistor device includes a drain contact on the Group III-nitride semiconductor structure. The first channel structure and the second channel structure each have a length extending in a first direction that is generally perpendicular to a second direction corresponding to a long dimension of the source contact and a long dimension of the drain contact.

Another example aspect of the present disclosure is directed to a method of forming a semiconductor device. The method includes forming a Group III-nitride semiconductor structure on a substrate. The method includes implanting dopants into the Group III-nitride semiconductor structure to form an isolation implant region in the Group III-nitride semiconductor structure. The isolation implant region separates the Group III-nitride semiconductor structure into a plurality of channel structures. The plurality of channel structures are electrically isolated from one another. The method includes forming a first contact on the Group III-nitride semiconductor structure. The method includes forming a second contact on the Group III-nitride semiconductor structure, the second contact spaced apart from the first contact. Each of the plurality of channel structures has a length extending between the first contact and the second contact. The isolation implant region extends along a length of one of the plurality of channel structures.

These and other features, aspects and advantages of various embodiments will become better understood with reference to the following description and appended claims. The accompanying drawings, which are incorporated in and constitute a part of this specification, illustrate embodiments of the present disclosure and, together with the description, explain the related principles.

### BRIEF DESCRIPTION OF THE DRAWINGS

Detailed discussion of embodiments directed to one of ordinary skill in the art are set forth in the specification, which refers to the appended figures, in which:

FIG. 1 depicts a plan view of an example semiconductor device;

FIG. 2 depicts a cross-sectional view along line A-A′ of the example semiconductor devices of FIGS. 1 and 3 according to example embodiments of the present disclosure;

FIG. 3 depicts a plan view of an example semiconductor device according to example embodiments of the preset disclosure;

FIG. 4 depicts an example cross-sectional view along line B-B′ of the example semiconductor device of FIG. 3 according to example embodiments of the present disclosure;

FIG. 5 depicts an example cross-sectional view of a semiconductor device according to example embodiments of the present disclosure;

FIG. 6 depicts an example cross-sectional view of a semiconductor device according to example embodiments of the present disclosure;

FIG. 7 depicts an example cross-sectional view of a semiconductor device according to example embodiments of the present disclosure;

FIG. 8 depicts an example cross-sectional view of a semiconductor device according to example embodiments of the present disclosure;

FIG. 9 depicts an example cross-sectional view of a semiconductor device according to example embodiments of the present disclosure; and

FIGS. 10A and 10B depicts a flow chart of an example method according to example embodiments of the present disclosure.

### DETAILED DESCRIPTION

Reference now will be made in detail to embodiments, one or more examples of which are illustrated in the drawings. Each example is provided by way of explanation of the embodiments, not limitation of the present disclosure. In fact, it will be apparent to those skilled in the art that various modifications and variations can be made to the embodiments without departing from the scope or spirit of the present disclosure. For instance, features illustrated or described as part of one embodiment can be used with another embodiment to yield a still further embodiment. Thus, it is intended that aspects of the present disclosure cover such modifications and variations.

Semiconductor devices, such as high electron mobility transistors (HEMTs), may be used in power electronics applications. HEMTs fabricated in Group III nitride-based material systems may have the potential to generate large amounts of radio frequency (RF) power because of the combination of material characteristics that includes high breakdown fields, wide bandgaps, large conduction band offset, and/or high saturated electron drift velocity. As such, Group III nitride based HEMTs may be promising candidates for high frequency and/or high-power RF applications, as well as for low frequency high power switching applications, both as discrete transistors or as coupled with other circuit elements, such as in monolithic microwave integrated circuit (MMIC) devices.

Transistor devices such as HEMT devices may be classified into depletion mode and enhancement mode types, corresponding to whether the transistor is in an ON-state or an OFF-state at a gate-source voltage of zero. In enhancement mode devices, the devices are OFF at zero gate-source voltage, whereas in depletion mode devices, the device is ON at zero gate-source voltage. Often, high performance Group III nitride-based HEMT devices may be implemented as depletion mode (normally-on) devices, in that they are conductive at a gate-source bias of zero due to the polarization-induced charge at the interface of the barrier and channel layers of the device.

When an HEMT device is in an ON-state, a two-dimensional electron gas (2DEG) is formed at the heterojunction of two semiconductor materials with different bandgap energies, where the smaller bandgap material has a higher electron affinity. The 2DEG is an accumulation layer in the smaller bandgap material and can include a very high sheet electron concentration. Additionally, electrons that originate in the wider-bandgap semiconductor material transfer to the 2DEG layer, allowing high electron mobility due to reduced ionized impurity scattering. This combination of high carrier concentration and high carrier mobility may give the HEMT device a very large transconductance (which may refer to the relationship between output current and input voltage) and may provide a strong performance advantage over MOSFETs for high-frequency applications.

Operating semiconductor devices, such as HEMTs, at higher operational frequencies (e.g., operational frequencies of about 8 GHz or greater) may lead to increased power density requirements for the semiconductor devices. The increased power density may result in increased heat generation in the semiconductor devices. This may cause increased operating junction temperatures for the semiconductor devices, potentially leading to thermal degradation of the semiconductor devices.

Aspects of the present disclosure are directed to incorporating isolation dopant implantation (e.g., nitrogen implantation) to create isolated or confined channel structures in a semiconductor device, such as an HEMT. The isolated channel structures may reduce electron trapping effects in the Group III-nitride semiconductor material during operation of the semiconductor device. Moreover, the isolated channel structures may provide for improved thermal conductivity of the semiconductor devices, allowing for increased thermal management and reduced thermal degradation of the semiconductor devices.

More particularly, in some embodiments, a semiconductor device may have a Group III-nitride semiconductor structure (e.g., a channel layer and a barrier layer on the channel layer such that a 2DEG is formed at an interface between the channel layer and the barrier layer). The Group III-nitride semiconductor structure may be etched or otherwise processed to form a plurality of isolated or confined channel structures in the Group III-nitride semiconductor structure. In some embodiments, a recess may be located between the plurality of isolated channel structures. A heat spreading layer (e.g., a layer with high thermal conductivity, such as about 80 W/(mk) or greater) may be on the plurality of isolated channel structures to provide a cooling path for heat generated in the semiconductor device during operation.

According to example aspects of the present disclosure, the semiconductor device may include an isolation implant region extending along a length of at least one of the plurality of channel structures. The isolation implant region may include implanted dopants, such as nitrogen, hydrogen, helium, zirconium, or oxygen. The isolation implant region may extend, for instance, through the Group III-nitride semiconductor structure to or into a substrate on which the Group III-nitride semiconductor structure is formed (e.g., a silicon carbide substrate). The isolation implant region may provide for electrical isolation between the isolated channel structures.

For instance, in some embodiments, a semiconductor device may include a substrate, such as a silicon carbide substrate. The semiconductor device may include a Group III-nitride semiconductor structure on the substrate. The semiconductor device may include a first contact (e.g., a source contact) on the Group III-nitride semiconductor structure. The semiconductor device may include a second contact (e.g., a drain contact) on the Group III-nitride semiconductor structure. The first contact and the second contact may be coplanar and spaced apart from one another. The Group III-nitride semiconductor structure may include a plurality of channel structures extending in a length direction between the first contact and the second contact. The semiconductor device comprises an isolation implant region extending along at least a portion of a length of at least one of the plurality of channel structures, wherein the isolation implant region comprises implanted dopants.

In some embodiments, a transistor device (e.g., an HEMT) may include a substrate, such as a silicon carbide substrate. The transistor device may include a Group III-nitride semiconductor structure on the substrate. The Group III-nitride semiconductor structure may include a first channel structure and a second channel structure that is electrically isolated from the first channel structure. The transistor device may include a source contact on the Group III-nitride semiconductor structure. The transistor device may include a drain contact on the Group III-nitride semiconductor structure. The first channel structure and the second channel structure each have a length extending in a first direction that is generally perpendicular to a second direction corresponding to a long dimension of the source contact and a long dimension of the drain contact.

Aspects of the present disclosure provide a number of technical effects and benefits. For instance, the sides of the channel structures of the Group III-nitride semiconductor structure may lead to electron trapping. Electron trapping may occur when electrons are captured and/or localized in potential energy wells, defects, or traps in the Group III-nitride semiconductor structure. The electron trapping may affect the transconductance of the 2DEG in an HEMT, potentially causing degraded performance due to, for instance, threshold voltage shift, degradation in gain and linearity, current collapse, or other performance issues. The present inventors have discovered that including the isolation implant region may not only provide for enhanced electrical isolation between the channel structures but may also reduce electron trapping. Moreover, the isolation implant region may provide for additional thermal extraction through the implant region at the edges of the channel structure to provide for improved thermal conduction between the transistor device and, for instance, a heat spreading layer formed on the Group III-nitride semiconductor structure to reduce heating in the semiconductor device.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms used herein should be interpreted as having a meaning that is consistent with their meaning in the context of this specification and the relevant art and will not be interpreted in an idealized or overly formal sense unless expressly so defined herein.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “lateral” or “vertical” may be used herein to describe a relationship of one element, layer or region to another element, layer or region as illustrated in the figures. It will be understood that these terms are intended to encompass different orientations of the device in addition to the orientation depicted in the figures.

Embodiments of the invention are described herein with reference to cross-section illustrations that are schematic illustrations of idealized embodiments (and intermediate structures) of the invention. The thickness of layers and regions in the drawings may be exaggerated for clarity. Additionally, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. Similarly, it will be understood that variations in the dimensions are to be expected based on standard deviations in manufacturing procedures. As used herein, “approximately” or “about” includes values within 10% of the nominal value.

Like numbers refer to like elements throughout. Thus, the same or similar numbers may be described with reference to other drawings even if they are neither mentioned nor described in the corresponding drawing. Also, elements that are not denoted by reference numbers may be described with reference to other drawings.

Some embodiments of the invention are described with reference to semiconductor layers and/or regions which are characterized as having a conductivity type such as n type or p type, which refers to the majority carrier concentration in the layer and/or region. Thus, N type material has a majority equilibrium concentration of negatively charged electrons, while P type material has a majority equilibrium concentration of positively charged holes. Some material may be designated with a “+” or “−” (as in N+, N−, P+, P−, N++, N−−, P++, P−−, or the like), to indicate a relatively larger (“+”) or smaller (“−”) concentration of majority carriers compared to another layer or region. However, such notation does not imply the existence of a particular concentration of majority or minority carriers in a layer or region.

As used herein, the term “generally perpendicular” refers to within 15° of perpendicular. As used herein, the term “generally parallel” refers to within 15° of parallel.

As used herein, the term “Group III nitride” refers to those semiconducting compounds formed between nitrogen (N) and the elements in Group III of the periodic table, usually aluminum (Al), gallium (Ga), and/or indium (In). The term also refers to ternary and quaternary (or higher) compounds such as, for example, AlGaN and AlInGaN. As is well understood by those in this art, the Group III elements can combine with nitrogen to form binary (e.g., GaN), ternary (e.g., AlGaN, AlInN), and quaternary (e.g., AlInGaN) compounds. These compounds all have empirical formulas in which one mole of nitrogen is combined with a total of one mole of the Group III elements. The semiconductor structure 102 may be metal-polar. However, aspects of the present disclosure are applicable to semiconductor devices having N-polar semiconductor structures without deviating from the scope of the present disclosure.

Aspects of the present disclosure are discussed with reference to an HEMT transistor device for purposes of illustration and discussion. Those of ordinary skill in the art, using the disclosures provided herein, will appreciate that certain aspects of the present disclosure may be applicable to other transistor devices without deviating from the scope of the present disclosure.

In the drawings and specification, there have been disclosed typical embodiments and, although specific terms are employed, they are used in a generic and descriptive sense only and not for purposes of limitation of the scope set forth in the following claims.

With reference now to the Figures, example embodiments of the present disclosure will now be set forth.

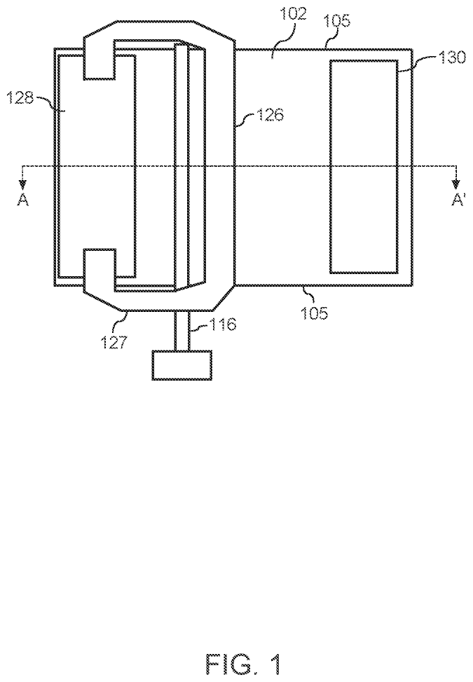

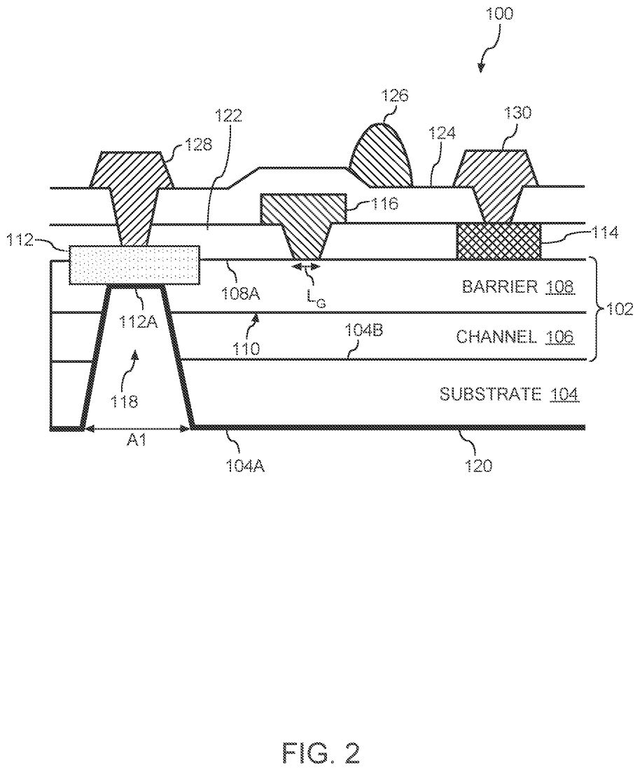

FIG. 1 depicts a plan view of an example semiconductor device 100 (e.g., and HEMT, such as a Group III-nitride based HEMT) according to example embodiments of the present disclosure. FIG. 2 is a cross-section of a portion of the semiconductor device 100 taken along line A-A′ of FIG. 1.

Referring to FIG. 1, metal portions of the semiconductor device 100 may include a source contact metallization 128 and a drain contact metallization 130. A gate contact 116 may be located between the source contact metallization 128 and the drain contact metallization 130. As will be discussed with reference to FIG. 2, the source contact metallization 128, the drain contact metallization 130 and the gate contact 116 may be on a Group III-nitride semiconductor structure 102. The semiconductor device may include an active area having one or more unit semiconductor device cells. Active area definition 105 defines the boundary of the active area. Anything outside of the active area may be electrically not conductive.

The semiconductor device 100 may include a field plate 126. The field plate 126 may be located between the gate contact 116 and the drain contact metallization 130. The field plate 126 may be connected to the source contact metallization 128 by at least one connection outside the active area of the device such that the connection does not cross over the gate contact 116. However, other suitable connections between the field plate 126 and the source contact metallization 128 or other structures may be provided without deviating from the scope of the present disclosure.

FIG. 2 depicts a cross-sectional view of the example semiconductor device 100 along line A-A′ of FIG. 1. FIG. 2 is intended to represent structures for identification and description and is not intended to represent the structures to physical scale. The semiconductor device 100 may include a semiconductor structure 102 (e.g., epitaxial semiconductor structure 102). The semiconductor structure 102 may be a Group III-nitride semiconductor structure.

The semiconductor structure 102 may be on a substrate 104. The substrate 104 may be a semiconductor material. For instance, the substrate 104 may be a silicon substrate, a silicon carbide (SiC) substrate, a sapphire substrate, or other suitable substrate. In some embodiments, the substrate 104 may be a semi-insulating SiC substrate that may be, for example, the 4H polytype of silicon carbide. Other SiC candidate polytypes may include the 3C, 6H, and 15R polytypes. The substrate may be a High Purity Semi-Insulating (HPSI) substrate, available from Wolfspeed, Inc. The term “semi-insulating” is used descriptively herein, rather than in an absolute sense.

In some embodiments, the SiC bulk crystal of the substrate 104 may have a resistivity equal to or higher than about 1×10⁵ ohm-cm at room temperature. Example SiC substrates that may be used in some embodiments are manufactured by, for example, Wolfspeed, Inc., and methods for producing such substrates are described, for example, in U.S. Pat. No. Re. 34,861, U.S. Pat. Nos. 4,946,547, 5,200,022, and 6,218,680, the disclosures of which are incorporated by reference herein. Although SiC may be used as a substrate material, embodiments of the present disclosure may utilize any suitable substrate, such as sapphire (Al₂O₃), aluminum nitride (AlN), aluminum gallium nitride (AlGaN), gallium nitride (GaN), silicon (Si), GaAs, LGO, zinc oxide (ZnO), LAO, indium phosphide (InP), and the like. The substrate 104 may be a SiC wafer, and the semiconductor device 100 may be formed, at least in part, via wafer-level processing, and the wafer may then be diced to provide a plurality of individual HEMT devices 100.

The substrate 104 may have a lower surface 104A and an upper surface 104B. In some embodiments, the substrate 104 of the semiconductor device 100 may be a thinned substrate 104. In some embodiments, the thickness of the substrate 104 (e.g., in a vertical Z direction in FIG. 2) may be about 100 μm or less, such as about 75 μm or less, such as about 50 μm or less.

The semiconductor device 100 may include a channel layer 106 on the upper surface 104B of the substrate 104 (or on the optional layers described further herein, such as an optional buffer layer or nucleation layer). The semiconductor device 100 may include a barrier layer 108 on an upper surface of the channel layer 106. In some embodiments, the channel layer 106 and the barrier layer 108 may each be formed by epitaxial growth. Techniques for epitaxial growth of Group III nitrides have been described in, for example, U.S. Pat. Nos. 5,210,051, 5,393,993, and 5,523,589, the disclosures of which are incorporated by reference herein. The channel layer 106 may have a bandgap that is less than the bandgap of the barrier layer 108. The channel layer 106 may have a larger electron affinity than the barrier layer 108. The channel layer 106 and the barrier layer 108 may include Group III-nitride based materials.

In some embodiments, the channel layer 106 may be a Group III nitride, such as Al_{w}Ga_{1-w}N, where 0≥w<1, provided that the energy of the conduction band edge of the channel layer 106 is less than the energy of the conduction band edge of the barrier layer 108 at the interface between the channel layer 106 and barrier layer 108. In some embodiments, the aluminum mole fraction w is approximately 0 (e.g., less than about 0.05), indicating that the channel layer 106 is GaN. The channel layer 106 may or may not include other Group III-nitrides such as InGaN, AlInGaN or the like. The channel layer 106 may be undoped (“unintentionally doped”) and may be grown to a thickness in the range of about 0.5 μm to about 5 μm, such as about 2 μm. The channel layer 106 may be a multi-layer structure, such as a superlattice or combinations of GaN, AlGaN or the like. The channel layer 106 may be under compressive strain in some embodiments.

The semiconductor structure 102 may include a barrier layer 108 on an upper surface of the channel layer 106. The barrier layer 108 may have a bandgap that is different from the bandgap of the channel layer 106. The energy of the conduction band edge of the barrier layer 108 may be greater than the energy of the conduction band edge of the channel layer 106 at the interface between the channel layer 106 and the barrier layer 108. The barrier layer 108 may be a Group III-nitride, such as AlₓGa₁₋ₓN, where x is the aluminum mole fraction in the barrier layer 108. In some embodiments, the aluminum mole fraction x is such that x is in a range of about 0.15 to about 0.40, such as about 0.20 to about 0.25, such as about 0.22 (e.g., the aluminum mole fraction is in a range of 15% to 40%, such as in a range of about 20% to about 25%, such as about 22%), indicating that the barrier layer is an AlGaN layer. The barrier layer 108 may include other Group III elements (e.g., In) without deviating from the scope of the present disclosure. The barrier layer 108, in some examples, may be a multilayer structure. The multilayer structure may include multiple Group III nitride-based layers with differing aluminum mole fractions. The barrier layer 108 may have a thickness in a range of about 10 Angstroms to about 400 Angstroms, such as about 120 Angstroms to about 170 Angstroms, such as about 150 Angstroms.

The channel layer 106 and/or the barrier layer 108 may be deposited, for example, by metal-organic chemical vapor deposition (MOCVD), molecular beam epitaxy (MBE), or hydride vapor phase epitaxy (HVPE). A 2DEG 110 may be induced in the channel layer 106 at an interface between the channel layer 106 and the barrier layer 108. The 2DEG 110 is highly conductive and allows conduction between the source and drain regions of the Semiconductor device 100.

While the semiconductor device 100 is shown with a substrate 104, channel layer 106 and barrier layer 108 for purposes of illustration, the semiconductor device 100 may include additional layers/structures/elements. For instance, the semiconductor device 100 may include a buffer layer and/or nucleation layer(s) between substrate 104 and the channel layer 106. For example, an AlN buffer layer may be on the upper surface 104B of the substrate 104 to provide an appropriate crystal structure transition between a SiC substrate 104 and the channel layer 106. The optional buffer/nucleation/transition layers may be deposited by MOCVD, MBE, and/or HYPE.

The semiconductor device 100 may include a cap layer on the barrier layer 108. Semiconductor devices (e.g., HEMT devices) including substrates, channel layers, barrier layers, and other layers are discussed by way of example in U.S. Pat. Nos. 5,192,987, 5,296,395, 6,316,793, 6,548,333, 7,544,963, 7,548,112, 7,592,211, 7,615,774, 7,709,269, 7,709,859 and 10,971,612, the disclosures of which are incorporated by reference herein. Additionally, strain balancing transition layer(s) may also and/or alternatively be provided as described, for example, in U.S. Pat. No. 7,030,428, the disclosure of which is incorporated by reference herein.

The semiconductor device 100 may include a source contact 112 on an upper surface 108A of the barrier layer 108 or otherwise contacting the barrier layer 108. The semiconductor device 100 may include a drain contact 114 on the upper surface 108A of the barrier layer 108 or otherwise contacting the barrier layer 108. The source contact 112 and the drain contact 114 may be laterally spaced apart from each other. In some embodiments, the source contact 112 and the drain contact 114 may include a metal that may form an ohmic contact to a Group III-nitride based semiconductor material. Suitable metals may include refractory metals, such as titanium (Ti), tungsten (W), titanium tungsten (TiW), silicon (Si), titanium tungsten nitride (TiWN), tungsten silicide (WSi), rhenium (Re), niobium (Nb), Ni, gold (Au), aluminum (Al), tantalum (Ta), molybdenum (Mo), NiSix, titanium silicide (TiSi), titanium nitride (TiN), tungsten silicon nitride (WSiN), platinum (Pt) and the like. In some embodiments, the source contact 112 may be an ohmic source contact 112. The drain contact 114 may be an ohmic drain contact 114. Thus, the source contact 112 and/or the drain contact 114 may include an ohmic contact portion in direct contact with the barrier layer 108. In some embodiments, the source contact 112 and/or the drain contact 114 may include a plurality of layers to form an ohmic contact that may be provided as described, for example, in U.S. Pat. Nos. 8,563,372 and 9,214,352, the disclosures of which are incorporated by reference herein.

The semiconductor device 100 may include a gate contact 116 on the upper surface 108A of the barrier layer 108 or otherwise contacting the barrier layer 108 (e.g., recessed into the barrier layer 108). The gate contact 116 may have a gate length LG. The gate length LG may be the length of the gate contact 116 at the portion of the gate contact 116 that is on the semiconductor structure 102 as illustrated in FIG. 2. In some embodiments, the gate length LG may be in the range of about 100 nm to about 400 nm, such as about 100 nm to about 350 nm. In some embodiments, the gate length LG may be about 100 nm or less, such as about 90 nm or less, such as about 60 nm or less. In some embodiments, the gate length LG may be in a range of about 40 nm to about 90 nm.

The material of the gate contact 116 may be chosen based on the composition of the barrier layer 108, and may, in some embodiments, be a Schottky contact. Materials capable of making a Schottky contact to a Group III-nitride based semiconductor material may be used, such as, for example, nickel (Ni), platinum (Pt), nickel silicide (NiSix), copper (Cu), palladium (Pd), chromium (Cr), tungsten (W), tungsten silicon nitride (WSiN), ruthenium (Ru), and/or p-type polysilicon.

The source contact 112 may be coupled to a reference signal such as, for example, a ground voltage or other reference signal. The coupling to the reference signal may be provided by a via 118 that extends from a lower surface 104A of the substrate 104, through the substrate 104 and the channel layer 106 to the upper surface 108A of the barrier layer 108. The via 118 may expose a bottom surface of the ohmic portion 112A of the source contact 112. A back metal layer 120 may be on the lower surface 104A of the substrate 104 and on side walls of the via 118. The back metal layer 120 may directly contact the ohmic portion 112A of the source contact 112. In some embodiments a contact area between the back metal layer 120 and the bottom surface of the ohmic portion 112A of the source contact 112 may be fifty percent or more of an area of the bottom surface of the ohmic portion 112A of the source contact 112. Thus, the back metal layer 120, and a signal coupled thereto, may be electrically connected to the source contact 112.

In some embodiments, the via 118 may have an oval or circular cross-section when viewed in a plan view. However, the present disclosure is not limited thereto. In some embodiments, a cross-section of the via 118 may be a polygon or other shape, as will be understood by one of ordinary skill in the art using the disclosures provided herein. In some embodiments, dimensions of the via (e.g., a length and/or a width) may be such that a largest cross-sectional area A1 of the via 118 is about 1000 μm² or less. The cross-sectional area A1 may be taken in a direction that is parallel to the lower surface 104A of the substrate 104 (e.g., the X-Y plane of FIG. 2). In some embodiments, the largest cross-sectional area A1 of the via 118 may be that portion of the via 118 that is adjacent the lower surface 104A of the substrate 104 (e.g., the opening of the via 118). For example, in some embodiments, a greatest width (e.g., in the X direction in FIG. 2) may be about 16 μm and a greatest length (e.g., in the Y direction in FIG. 2) may be about 40 μm, though the present disclosure is not limited thereto. In some embodiments, sidewalls of the via 118 may be inclined and/or slanted with respect to the lower surface 104A of the substrate 104. In some embodiments, the sidewalls of the via 118 may be approximately perpendicular to the lower surface 104A of the substrate 104.

Depending on the embodiment, the drain contact 114 may be formed on, in and/or through the barrier layer 108, and there can be ion implantation into the materials around the drain contact 114 (e.g., through the barrier layer 108 and into the channel layer 106) to reduce resistivity and provide improved ohmic contact to the semiconductor material. In yet other embodiments, there is no source via 118, and the source contact 112 is formed on, in and/or through the barrier layer 108, and there can be ion implantation in the materials around the source contact 112 to reduce resistivity and provide improved ohmic contact to the semiconductor material. In some examples, the connections to the source contact 112, drain contact 114, and/or gate contact 116 can be made from the top and/or the bottom to provide for flip chip configuration of the semiconductor device 100. In some examples, thermal paths may be provided from the top and/or bottom to provide for flip chip configuration of the semiconductor device 100.

The semiconductor device 100 may include a first insulating layer 122. The first insulating layer 122 may directly contact the upper surface of the semiconductor structure 102 (e.g., contact the upper surface 108A of the barrier layer 108). The Semiconductor device 100 may include a second insulating layer 124. The second insulating layer 124 may be on the first insulating layer 122. It will also be appreciated that more than two insulating layers may be included in some embodiments. The first insulating layer 122 and/or the second insulating layer 124 may serve as passivation layers for the Semiconductor device 100. The first insulating layer 122 and/or the second insulating layer 124 may be dielectric layers. Different dielectric materials may be used such as AlN, SiN, SiO2, Al₂O₃ MgOx, MgNx, ZnO, SiNx, SiOx, alloys or layer sequences thereof, or epitaxial materials.

The source contact 112, the drain contact 114, and the gate contact 116 may be in the first insulating layer 122. In some embodiments, at least a portion of the gate contact 116 may be on the first insulating layer 122. In some embodiments, the gate contact 116 may be a T-shaped gate and/or a gamma gate, the formation of which is discussed by way of example in U.S. Pat. Nos. 8,049,252, 7,045,404, and 8,120,064, the disclosures of which are incorporated by reference herein. The second insulating layer 124 may be on the first insulating layer 122 and on portions of the source contact 112, drain contact 114, and gate contact 116. The protrusions from the gate can also be referred to as a field plate integrated with the gate.

A field plate 126 may be on the second insulating layer 124 as illustrated in FIG. 2, or on another insulating layer depending on the number of insulating layers included in the semiconductor device 100. In some embodiments (not illustrated) at least a portion of a field plate 126 may be at least partially overlapping the gate contact 116. In some embodiments, at least a portion of the field plate 126 may be on a portion of the second insulating layer 124 that is between the gate contact 116 and the drain contact 114. The field plate 126 may reduce the peak electric field in the Semiconductor device 100, which may result in increased breakdown voltage and reduced charge trapping. The reduction of the electric field can also yield other benefits such as reduced leakage currents and enhanced reliability. Field plates and techniques for forming field plates are discussed, by way of example, in U.S. Pat. No. 8,120,064, the disclosure of which is incorporated by reference herein.

The source contact metallization 128 and the drain contact metallization 130 may be on the second insulating layer 124 as illustrated in FIG. 2. The source contact metallization 128 may be electrically coupled to the source contact 112. The drain contact metallization 130 may be electrically coupled to the drain contact 114. The source contact metallization 128 and the drain contact metallization 130 may include metal or other highly conductive material, including, for example, copper, cobalt, gold, and/or a composite metal.

A HEMT transistor may be formed by the active region between the source contact 112 and the drain contact 114 under the control of a gate contact 116 between the source contact 112 and the drain contact 114. FIG. 2 depicts a cross-sectional view of one unit of an Semiconductor device 100 for purposes of illustration. The Semiconductor device 100 may be formed adjacent to additional HEMT device units and may share, for instance, a source contact 112 with adjacent HEMT device units.

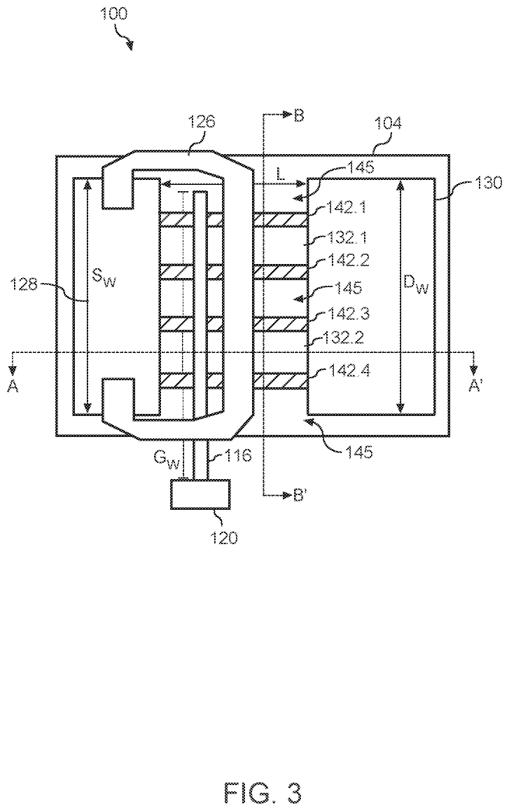

FIG. 3 depicts a semiconductor device 100 that includes a plurality of isolated channel structures 132.1, 132.2 . . . 132.n according to example embodiments of the present disclosure. Each of the isolated channel structures 132.1, 132.2 . . . 132.n may be electrically isolated from one another. FIG. 3 depicts a semiconductor device with two isolated channel structures 132.1 and 132.2. However, those of ordinary skill in the art, using the disclosures provided herein, will understand that the semiconductor device 100 may include more or fewer isolated channel structures without deviating from the scope of the present disclosure, such as three isolated channel structures, such as four isolated channel structures, such as ten isolated channel structures, such as 20 isolated channel structures, or any other number of isolated channel structures.

The semiconductor device 100 of FIG. 3 is similar to that of FIG. 1 with the exception of having isolated channel structures 132.1 and 132.2 in the Group III-nitride semiconductor structure 102. The isolated channel structures 132.1 and 132.2 each have a length L (e.g., a long dimension). The isolated channel structures 132.1 and 132.2 extend in the length direction (e.g., the direction along the long dimension) between the source contact metallization 128 and the drain contact metallization 130. The cross-section along line A-A′ within one of the channel structures 132.1 is the same as than along line A-A′ of FIG. 1 and is illustrated in FIG. 2. More particularly, the Group III-nitride semiconductor structure 102 in each channel structure 132.1 and 132.2 can include a channel layer 106 and a barrier layer 108 on the channel layer 106 as discussed about with respect to FIG. 2.

As shown in FIG. 3, the gate contact 116 may include a dimension Gw defined as the long dimension of the gate contact. The long dimension Gw may extend in a direction generally perpendicular to the length L of the isolated channel structures 132.1, 132.2 . . . 132.n. Similarly, the source contact metallization 128 may have a dimension Sw defined as the long dimension of the source contact metallization 128. The long dimension Sw may extend in a direction generally perpendicular to the length L of the isolated channel structures 132.1, 132.2 . . . 132.n. Similarly, the drain contact metallization 130 may have a dimension Dw defined as the long dimension of the drain contact metallization 130. The long dimension Dw may extend in a direction generally perpendicular to the length L of the isolated channel structures 132.1, 132.2 . . . 132.n.

According to example embodiments of the present disclosure, the Group III-nitride semiconductor structure 102 may include one or more isolation implant regions 142.1, 142.2, 142.3, 142.4 . . . 142.n extending along a length of at least one of the plurality of isolated channel structures 132.1 and 132.2. The one or more isolation implant regions 142.1, 142.2, 142.3, 142.4 . . . 142.n may include implanted dopants. The dopants may include, for instance nitrogen, hydrogen, helium, zirconium, and/or oxygen.

The one or more isolation implant regions 142.1, 142.2, 142.3, 142.4 . . . 142.n may provide electrical isolation between the isolated channel structures 132.1 and 132.2. In addition, the Group III-nitride semiconductor structure 102 may include a recess 145. The recess 145 may enhance the electrical isolation between the isolated channel structures 132.1 and 132.2.

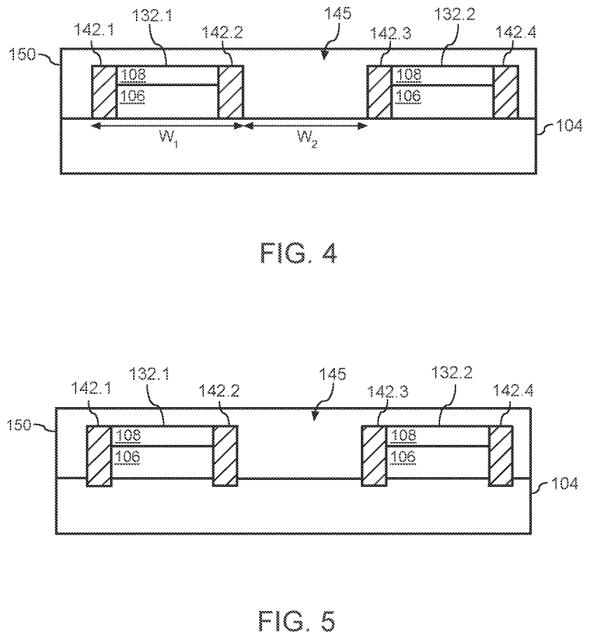

FIG. 4 depicts a cross-sectional view of the semiconductor device 100 of FIG. 3 taken along line B-B′. As shown, a Group III-nitride semiconductor structure 102 is on a substrate 104. The Group III-nitride semiconductor structure 102 includes a plurality of isolated channel structures 132.1 and 132.2. The isolated channel structures 132.1 and 132.2 include a channel layer 106 and a barrier layer 108 on the channel layer 106.

Each isolated channel structure 132.1 and 132.2 includes one or more isolation implant regions. For instance, isolated channel structure 132.1 includes a first isolation implant region 142.1 along a first edge of the isolated channel structure 132.1. The isolated channel structure 132.1 includes a second isolation implant region 142.2 along a second edge of the isolated channel structure 132.1 that is opposite the first isolation implant region 142.1.

Similarly, for instance, the isolated channel structure 132.2 includes a third isolation implant region 142.3 along a first edge of the isolated channel structure 132.2. The isolated channel structure 132.2 includes a fourth isolation implant region 142.4 along a second edge of the isolated channel structure 132.2 opposite the third isolation implant region 142.3.

According to example aspects of the present disclosure, the isolation implant regions 142.1, 142.2, 142.3, and 142.4 extend to a depth in the semiconductor structure sufficient to provide electrical isolation between the isolated channel structures 132.1 and 132.2. For instance, the isolation implant regions 142.1 and 142.2 may extend through the channel structure 132.1 to an interface between the channel structure 132.1 and the substrate 104. The isolation implant regions 142.4 and 142.4 may extend through the channel structure 132.2 to an interface between the channel structure 132.2 and the substrate 104. In the example of FIG. 4, each of the implant regions 142.1, 142.2, 142.3, and 142.4 extend to a same depth. However, the implant regions 142.1, 142.2, 142.3, and 142.4 may extend to varying depths without deviating from the scope of the present disclosure.

The isolation implant regions 142.1, 142.2, 142.3, and 142.4 may extend to other depths without deviating from the scope of the present disclosure. For example, FIG. 5 depicts a semiconductor device with a plurality of isolated channel structures 132.1 and 132.2. The isolation implant regions 142.1 and 142.2 within the first isolated channel structure 132.1 extend all the way through the channel structure 132.1 to a depth within the substrate 104. The isolation implant regions 142.3 and 142.4 within the second isolated channel structure 132.2 extend all the way through the channel structure 132.2 to a depth within the substrate 104.

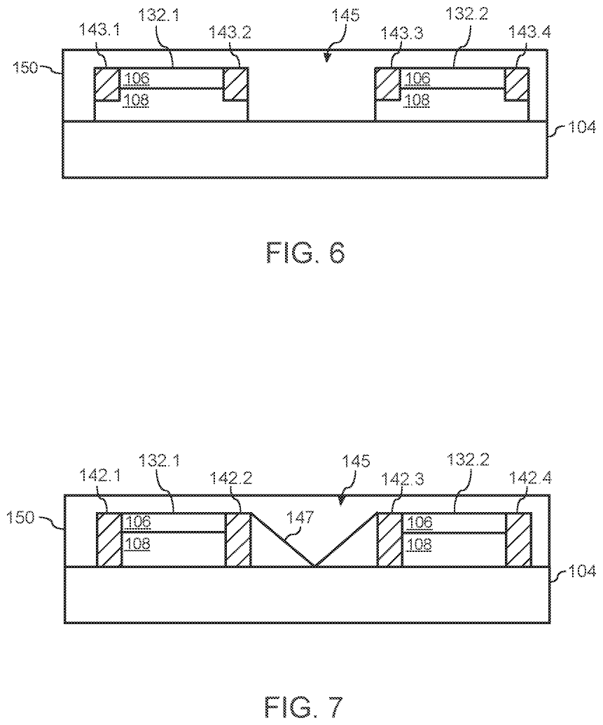

As another example, FIG. 6 depicts a semiconductor device with a plurality of isolated channel structures 132.1 and 132.2. The isolation implant regions 142.1, 142.2, 142.3, and 142.4 extend partially through a thickness of the channel structures 132.1 and 132.2, such as in a range of about 50% to about 95% through a thickness of the channel structure 132.1.

Referring back to FIG. 4, the isolation implant regions 142.1, 142.2, 142.3, and 142.4 may include a distribution of dopants. The dopants may include one or more of nitrogen, hydrogen, helium, zirconium, magnesium, and/or oxygen. The distribution of dopants may have a peak dopant concentration. For instance, in some examples, the distribution of dopants may have a peak dopant concentration of at least about 1×10¹⁸ dopants/cm³.

In some examples, the peak dopant concentration may be located in the isolation implant region 142.1, 142.2, 142.3, and 142.4 at a location proximate an interface between the barrier layer 108 and the channel layer 106. For instance, in the example of FIG. 4, the peak distribution of dopants in the isolation implant region 142.1, 142.2, 142.3, and 142.4 may be in a region within 250 Angstroms or less of the interface between the barrier layer 108 and the channel layer 106.

The peak dopant concentration may be in different regions within the isolation implant region 132 of FIG. 4. For instance, in some examples, the peak dopant concentration may be located in the isolation 142.1, 142.2, 142.3, 142.4 . . . 142.n in a region at a location proximate an interface between the isolated channel structure 132.1 and 132.2 and the substrate 104 in the Group III-nitride semiconductor structure, such as within 250 Angstroms or less of the substrate.

The peak dopant concentration may be in different regions within the isolation implant regions 142.1, 142.2, 142.3, 142.4. For instance, the peak dopant concentration may in region closer to a surface of the isolated channel structures 132.1 and 132.2. The distribution of dopants may vary as a function of depth within the isolation implant regions 142.1, 142.2, 142.3, 142.4. In some examples, the distribution of dopants may have spikes or peaks within multiple regions with the dopant concentration being less in other regions of the isolation implant region 142.1, 142.2, 142.3, . . . 142.4. In some examples, the dopant concentration may be nearly uniform throughout the isolation implant region 142.1, 142.2, 142.3, and 142.4.

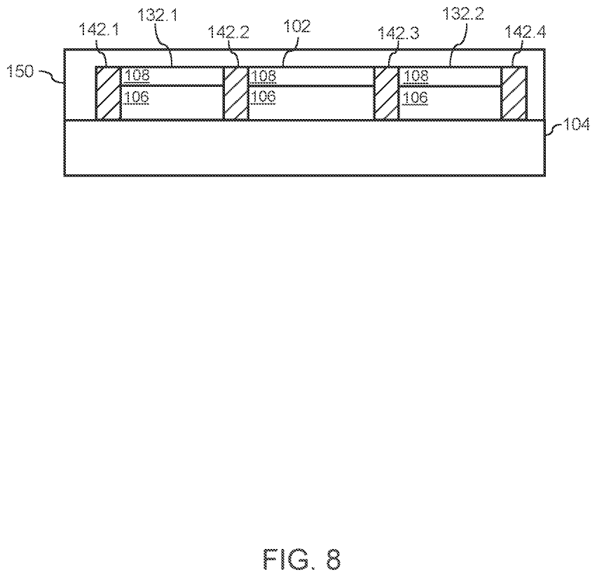

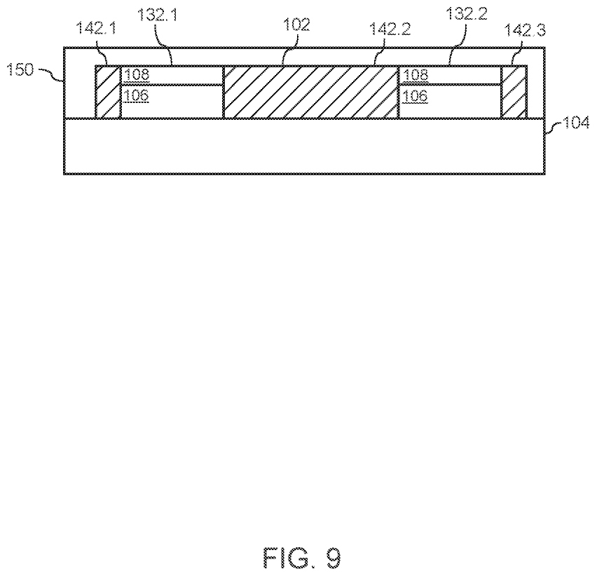

The Group III-nitride semiconductor structure 102 may include a recess 145 between the isolated channel structures 132.1 and 132.2. The recess 145 may provide enhanced electrical isolation between the isolated channel structure 132.1 and 132.2. The recess 145 may have any suitable shape. For instance, the recess 145 in FIG. 4 may have nearly straight sidewalls. The recess 145 may extend all the way through the Group III-nitride semiconductor structure 102 to the substrate 104 and/or into the substrate 104. In other examples, the recess 135 may have sloped sidewalls 147 as shown in FIG. 7. In some examples, there is no recess 145 between the isolated channel structures 132.1 and 132.2 as shown in FIG. 8. In some examples, as shown in FIG. 9, an implanted region 142.2 extends entirely between the isolated channel structures 132.1 and 132.2. The implanted region 142.2 may extend partially between the isolated channel structures 132.1 and 132.2 without deviating from the scope of the present disclosure.

Referring to FIG. 4, each of the isolated channel structures 132.1 and 132.2 may have a width W1. The width W1 may be for instance, about 20 microns to about 200 microns. The recess 145 may also have a width W2. A ratio of the width W1 to the width W2 may be, for instance, in a range of about 0.5:1 to about 2:1, such as about 1:1.

In some examples, the semiconductor device 100 may include a heat spreading layer 150 on the isolated channel structures 132.1 and 132.2. In some examples, the heat spreading layer 150 may be located at least partially in the recess 145. The heat spreading layer 150 may provide a thermally conductive path for each of the isolated channel structures 132.1 and 132.2 to a surface of the semiconductor device 100. The heat spreading layer 150 may be a single layer or may be a multilayer structure. In some examples, the heat spreading layer 150 includes one or more metal layers. In some examples, the heat spreading layer 150 includes one or more dielectric layers. In some examples, the heat spreading layer 150 has a thermal conductivity of about 80 W/(mk) or greater. In some examples, the heat spreading layer 150 is one or more of diamond, silicon carbide, aluminum nitride, boron nitride, or beryllium oxide.

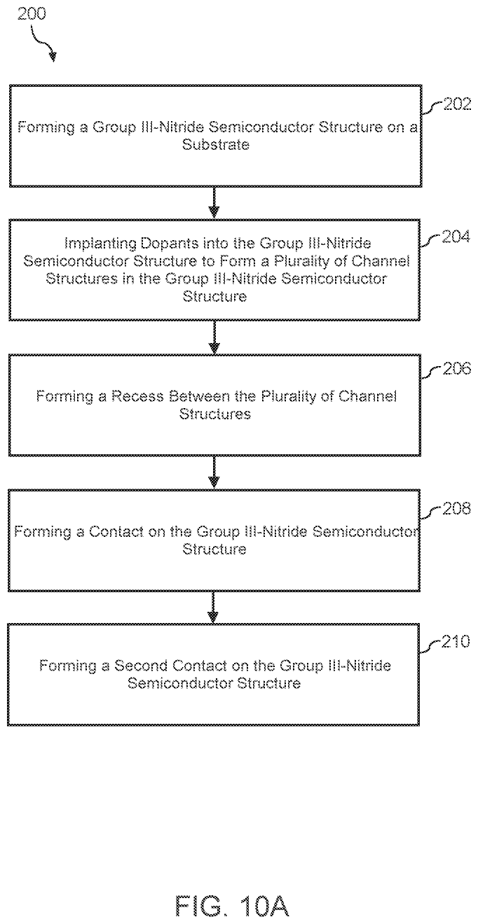

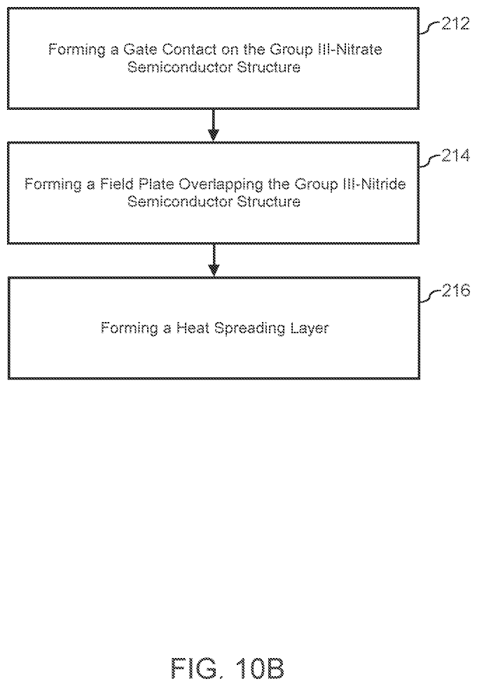

FIG. 10A depicts a flow diagram of an example method 200 according to example embodiments of the present disclosure. FIG. 10A depicts steps performed in a particular order for purposes of illustration and discussion. Those of ordinary skill in the art, using the disclosures provided herein, will understand that the various operations, steps, of any of the methods provided herein may be adapted, modified, expanded, include steps not illustrated, omitted, and/or rearranged without deviating from the scope of the present disclosure.

At 202, the method 200 may include forming a Group III-nitride semiconductor structure on a substrate. For instance, the method 200 may include forming a Group III-nitride semiconductor structure 102 on a substrate 104, such as a silicon carbide substrate 104. The semiconductor structure 102 may be a multilayer structure and may include one or more of a barrier layer 108, a channel layer 106, and other layers. For instance, the Group III-nitride semiconductor structure can include a channel layer and a barrier layer on the channel layer as discussed with reference to FIG. 2. The Group III-nitride semiconductor structure may be formed, for instance, using metal-organic chemical vapor deposition (MOCVD), molecular beam epitaxy (MBE), or hydride vapor phase epitaxy (HVPE).

At 204, the method 200 may include implanting dopants in the Group III-nitride semiconductor structure to form an isolation implant region. The isolation implant region may separate the Group III-nitride semiconductor structure into a plurality of channel structures. Each of the channel structures may be electrically isolated from one another. For instance, the method 200 may include forming one or more of implanted regions 142.1, 142.2, 142.3, and 142.4 in the Group III-nitride semiconductor structure 102 to form the isolated channel structures 132.1 and 132.2 as shown in FIGS. 3-8.

In some examples, a mask may be formed on the Group III-nitride semiconductor structure. The mask may include photoresist or any other suitable mask material, such as SiN and/or SiO₂. The mask may have a thickness selected to block implanted dopants during an implantation process. Next, windows can be opened in the mask to expose surface portions of the semiconductor structure. An implantation process is performed to implant dopants through the windows into the semiconductor structure such that at least a portion of the implanted dopants are implanted through the semiconductor structure and come to rest within the semiconductor structure, forming the isolation implant region(s).

The implanted dopants may include one or more of nitrogen, hydrogen, helium, zirconium, or oxygen. The implant conditions may be selected to provide implant region(s) having a peak dopant concentration of 1×10¹⁸ ions/cm³ or greater. The implant conditions may also be selected to provide a distribution of implanted dopants, such as distribution having a substantially uniform concentration throughout the implanted region(s). In some examples, the implant conditions may be selected such that the implanted region(s) have a distribution of implanted dopants in the implanted region(s) with a peak dopant concentration at a depth within about 250 Angstroms or less of the substrate. Other implant conditions may be used without deviating from the scope of the present disclosure.

In some embodiments, the implant process may include multiple implant steps. The number of implant steps may depend on the thickness of the semiconductor structure and the depth of the implanted region(s). For example, the implant process may include a first implant step performed under a first set of implant conditions, and a subsequent implant step performed under a second set of implant conditions. However, more than two implant steps may be performed to provide the implanted region(s).

In some embodiments, the dopant implantation process may be performed at room temperature. In some embodiments, the implanted dopants may be activated by an activation anneal. The mask may be removed prior to the implant activation anneal, for example, by way of a photoresist strip process and/or an etch process. However, the activation anneal may be performed with the mask in place. After the implantation process, the mask may be removed.

At 206, the method 200 may include forming a recess between the plurality of channel structures. For instance, the method may include forming the recess 145 between the plurality of channel structures 132.1 and 132.2 as shown in FIGS. 3 and 4. The recess may provide enhanced electrical isolation between the isolated channel structures. The recess may have any suitable shape. For instance, the recess may have nearly straight sidewalls. The recess may extend all the way through the Group III-nitride semiconductor structure to the substrate and/or into the substrate. In some examples, the recess may have sloped sidewalls. In some examples, the recess may be formed using an etch process, such as a wet etch process, plasma-based etch process, or atomic layer etch (ALE) process. In some examples, each of the isolated channel structures may have a width W1. The width W1 may be, for instance, about 20 microns to about 200 microns. The recess may also have a width. A ratio of the width W1 to the width W2 may be, for instance, in a range of about 0.5:1 to about 2:1, such as about 1:1.

At 208, the method 200 includes forming a first contact on the Group III-nitride semiconductor structure. The first contact may be, for instance, a source contact (e.g., source contact metallization 128 of FIG. 3). The first contact may form an ohmic contact with the Group III-nitride semiconductor structure. The first contact may have a long dimension extending generally perpendicular to the plurality of channel structures. The first contact may be formed using a suitable metal deposition process, such as a chemical vapor deposition (CVD) process, a physical vapor deposition (PVD) process, a sputtering process, an atomic layer deposition (ALD) process, or other suitable deposition process.

At 210, the method includes forming a second contact on the Group III-nitride semiconductor structure. The second contact may be, for instance, a drain contact (e.g., drain contact metallization 130 of FIG. 3). The second contact may form an ohmic contact with the Group III-nitride semiconductor structure. The second contact may have a long dimension extending generally perpendicular to the plurality of channel structures. The second contact may be formed using a suitable metal deposition process, such as a chemical vapor deposition (CVD) process, a physical vapor deposition (PVD) process, a sputtering process, an atomic layer deposition (ALD) process, or other suitable deposition process.

FIG. 10B depicts a flow chart of additional method steps that may be implemented as part of method 200 in some examples. FIG. 10B depicts steps performed in a particular order for purposes of illustration and discussion. Those of ordinary skill in the art, using the disclosures provided herein, will understand that the various operations, steps, of any of the methods provided herein may be adapted, modified, expanded, include steps not illustrated, omitted, and/or rearranged without deviating from the scope of the present disclosure.

At 212, the method 200 includes forming a gate contact on the Group III-nitride semiconductor structure. For instance, the method 200 may include forming the gate contact 116 on the semiconductor structure 102 as shown in FIG. 3. The gate contact may have a long dimension GL extending generally perpendicular to the plurality of channel structures. The gate contact may be formed using a suitable metal deposition process, such as a chemical vapor deposition (CVD) process, a physical vapor deposition (PVD) process, a sputtering process, an atomic layer deposition (ALD) process, or other suitable deposition process.

At 214, the method 200 may include forming a field plate overlapping the Group III-nitride semiconductor structure. For instance, the method 200 may include forming the field plate 126 on the semiconductor structure 102 as shown in FIG. 3. In some examples, the field plate may be coupled to a source contact. The field plate may be formed using a suitable metal deposition process, such as a chemical vapor deposition (CVD) process, a physical vapor deposition (PVD) process, a sputtering process, an atomic layer deposition (ALD) process, or other suitable deposition process.

At 216, the method 200 may include forming a heat spreading layer on the semiconductor structure. For instance, the method may include forming the heat spreading layer 150 shown in FIGS. 4-8. In some examples, the heat spreading layer may be located at least partially in the recess. The heat spreading layer may provide a thermally conductive path for each of the isolated channel structures to a surface of the semiconductor device. The heat spreading layer may be a single layer or may be a multilayer structure. In some examples, the heat spreading layer includes one or more metal layers. In some examples, the heat spreading layer includes one or more dielectric layers. In some examples, the heat spreading layer has a thermal conductivity of about 80 W/(mk) or greater. In some examples, the heat spreading layer is one or more of diamond, silicon carbide, aluminum nitride, boron nitride, or beryllium oxide. The heat spreading layer may be formed using a suitable metal deposition process, such as a chemical vapor deposition (CVD) process, a physical vapor deposition (PVD) process, a sputtering process, an atomic layer deposition (ALD) process, or other suitable deposition process.

Example aspects of the present disclosure are set forth below. Any of the below features or examples may be used in combination with any of the embodiments or features provided in the present disclosure.

One example aspect of the present disclosure is directed to a semiconductor device. The semiconductor device includes a Group III-nitride semiconductor structure. The semiconductor device includes a first contact on the Group III-nitride semiconductor structure. The semiconductor device includes a second contact on the Group III-nitride semiconductor structure. The second contact is spaced apart from the first contact. The Group III-nitride semiconductor structure includes a plurality of channel structures extending in a length direction between the first contact and the second contact. The semiconductor device includes an isolation implant region extending along at least a portion of a length of at least one of the plurality of channel structures. The isolation implant region comprises implanted dopants.

In some examples, the Group III-nitride semiconductor structure has a recess between the plurality of channel structures. In some examples, the recess extends through the Group III-nitride semiconductor structure to a substrate. In some examples, the recess has one or more sloped sidewalls. In some examples, each channel structure of the plurality of channel structures has a first width and the recess between the plurality of channel structures has a second width, wherein a ratio of the first width to the second width is in a range of about 0.5:1 to about 2:1. In some examples, the semiconductor device further comprises a heat spreading layer on the plurality of channel structures and in the recess.

In some examples, each channel structure comprises a channel layer and a barrier layer, the barrier layer having a different bandgap relative to the channel layer.

In some examples, the first contact includes a source contact and the second contact includes a drain contact. The semiconductor device further includes a gate contact. The gate contact has a long dimension extending generally perpendicular to the length of the plurality of channel structures.

In some examples, the semiconductive device includes a field plate.

In some examples, each channel structure comprises a second isolation implant region in the channel structure opposite the isolation implant region.

In some examples, the isolation implant region extends through the channel structure to an interface between the channel structure and the substrate. In some examples, the isolation implant region extends at least partially into the substrate.

In some examples, the implanted dopants comprise one or more of nitrogen, hydrogen, helium, zirconium, or oxygen. In some examples, the implanted dopants have a peak dopant concentration at a depth in the isolation implant region within about 250 Angstroms or less of the substrate. In some examples, the implanted dopants have a peak dopant concentration of at least about 1×10¹⁸ dopants/cm³.

In some examples, the Group III-nitride semiconductor structure is an N-polar Group III-nitride semiconductor structure. In some examples, the Group III-nitride semiconductor structure is on a substrate, the substrate comprising silicon carbide. In some examples, the semiconductor device comprises a high electron mobility transistor.

Another example aspect of the present disclosure is directed to a transistor device. The transistor device includes a substrate. The transistor device includes a Group III-nitride semiconductor structure on the substrate. The Group III-nitride semiconductor structure includes a first channel structure and a second channel structure that is electrically isolated from the first channel structure. The transistor device includes a source contact on the Group III-nitride semiconductor structure. The transistor device includes a drain contact on the Group III-nitride semiconductor structure. The first channel structure and the second channel structure each have a length extending in a first direction that is generally perpendicular to a second direction corresponding to a long dimension of the source contact and a long dimension of the drain contact.

In some examples, the first channel structure includes: a first implanted region at a first edge of the first channel structure; and a second implanted region at a second edge of the first channel structure, the second edge of the first channel structure being opposite the first edge of the first channel structure. In some examples, the first implanted region and the second implanted region extend along the length of the first channel structure. In some examples, the second channel structure includes: a third implanted region at a first edge of the second channel structure; and a fourth implanted region at a second edge of the second channel structure, the second edge of the second channel structure being opposite the first edge of the second channel structure. In some examples, the third implanted region and the fourth implanted region extend along the length of the second channel structure.

In some examples, each of the first implanted region, the second implanted region, the third implanted region, and the fourth implanted region comprise a distribution of implanted dopants. In some examples, the implanted dopants comprise one or more of nitrogen, hydrogen, helium, zirconium, or oxygen. In some examples, the distribution of implanted dopants has a peak dopant concentration at a depth within about 250 Angstroms or less of the substrate. In some examples, the distribution of implanted dopants has a peak dopant concentration of at least about 1×10¹⁸ dopants/cm³.

In some examples, each of the first implanted region, the second implanted region, the third implanted region, and the fourth implanted region extends to an interface with the substrate. In some examples, each of the first implanted region, the second implanted region, the third implanted region, and the fourth implanted region extends at least partially into the substrate.

In some examples, the Group III-nitride semiconductor structure includes a recess between the first channel structure and the second channel structure. In some examples, the recess extends through the Group III-nitride semiconductor structure to the substrate. In some examples, the recess has one or more sloped sidewalls. In some examples, the first channel structure and the second channel structure have a first width and the recess between the first channel structure and the second channel structure has a second width, wherein a ratio of the first width to the second width is in a range of about 0.5:1 to about 2:1. In some examples, the transistor device further comprises a heat spreading layer on the first channel structure and the second channel structure and in the recess.

In some examples, the transistor device further includes a gate contact. The gate contact has a long dimension extending generally perpendicular to the length of the first channel structure. In some examples, the transistor device includes a field plate.

In some examples, each of the first channel structure and the second channel structure includes a channel layer and a barrier layer. The barrier layer has a different bandgap relative to the channel layer.

In some examples, the substrate includes silicon carbide. In some examples, the transistor device includes a high electron mobility transistor.

Another example aspect of the present disclosure is directed to a method of forming a semiconductor device. The method includes forming a Group III-nitride semiconductor structure on a substrate. The method includes implanting dopants into the Group III-nitride semiconductor structure to form an isolation implant region in the Group III-nitride semiconductor structure. The isolation implant region separates the Group III-nitride semiconductor structure into a plurality of channel structures. The plurality of channel structures are electrically isolated from one another. The method includes forming a first contact on the Group III-nitride semiconductor structure. The method includes forming a second contact on the Group III-nitride semiconductor structure, the second contact spaced apart from the first contact. Each of the plurality of channel structures has a length extending between the first contact and the second contact. The isolation implant region extends along a length of one of the plurality of channel structures.

In some examples, the method includes forming a recess between the plurality of channel structures. In some examples, the recess extends through the Group III-nitride semiconductor structure to the substrate. In some examples, the recess has one or more sloped sidewalls. In some examples, each channel structure has a first width and the recess between the plurality of channel structures has a second width. A ratio of the first width to the second width is in a range of about 0.5:1 to about 2:1.

In some examples, the method includes forming a heat spreading layer on the plurality of channel structures.

In some examples, implanting dopants includes implanting dopants including one or more of nitrogen, hydrogen, helium, zirconium, or oxygen. In some examples, implanting dopants includes implanting dopants such that a distribution of implanted dopants in the isolation implant region has a peak dopant concentration at a depth within about 250 Angstroms or less of the substrate. In some examples, implanting dopants includes implanting dopants such that a distribution of implanted dopants in the isolation implant region has a peak dopant concentration of at least about 1×10¹⁸ dopants/cm³.

In some examples, implanting dopants includes implanting dopants such that the isolation implant region extends to an interface with the substrate. In some examples, implanting dopants includes implanting dopants such that the isolation implant region extends at least partially into the substrate.

In some examples, the first contact is a source contact and the second contact is a drain contact. The method includes forming a gate contact on the Group III-nitride semiconductor structure. The gate contact has a long dimension extending generally perpendicular to the length of each of the plurality of channel structures.

In some examples, the method includes forming a field plate overlapping the Group III-nitride semiconductor structure.

In some examples, each of the plurality of channel structures includes a channel layer and a barrier layer. The barrier layer has a different bandgap relative to the channel layer.

In some examples, the substrate includes silicon carbide. In some examples, the semiconductor device includes a high electron mobility transistor.

While the present subject matter has been described in detail with respect to specific example embodiments thereof, it will be appreciated that those skilled in the art, upon attaining an understanding of the foregoing may readily produce alterations to, variations of, and equivalents to such embodiments. Accordingly, the scope of the present disclosure is by way of example rather than by way of limitation, and the subject disclosure does not preclude inclusion of such modifications, variations and/or additions to the present subject matter as would be readily apparent to one of ordinary skill in the art.

1. A semiconductor device, comprising:
a Group III-nitride semiconductor structure;
a first contact on the Group III-nitride semiconductor structure;
a second contact on the Group III-nitride semiconductor structure, the second contact spaced apart from the first contact;
wherein the Group III-nitride semiconductor structure comprises a plurality of channel structures extending in a length direction between the first contact and the second contact; and
wherein the semiconductor device comprises an isolation implant region extending along at least a portion of a length of at least one of the plurality of channel structures, wherein the isolation implant region comprises implanted dopants.

2. The semiconductor device of claim 1, wherein the Group III-nitride semiconductor structure has a recess between the plurality of channel structures.

3. The semiconductor device of claim 2, wherein the recess extends through the Group III-nitride semiconductor structure to a substrate.

4. The semiconductor device of claim 2, wherein the recess has one or more sloped sidewalls.

5. The semiconductor device of claim 2, wherein each channel structure of the plurality of channel structures has a first width and the recess between the plurality of channel structures has a second width, wherein a ratio of the first width to the second width is in a range of about 0.5:1 to about 2:1.

6. The semiconductor device of claim 2, wherein the semiconductor device further comprises a heat spreading layer on the plurality of channel structures and in the recess.

7. The semiconductor device of claim 1, wherein each channel structure comprises a channel layer and a barrier layer, the barrier layer having a different bandgap relative to the channel layer.

8. The semiconductor device of claim 1, wherein the first contact comprises a source contact and the second contact comprises a drain contact, wherein the semiconductor device further comprises a gate contact, the gate contact having a long dimension extending generally perpendicular to the length of the plurality of channel structures.

9. The semiconductor device of claim 1, further comprising a field plate.

10. The semiconductor device of claim 1, wherein each channel structure comprises a second isolation implant region in the channel structure opposite the isolation implant region.

11. The semiconductor device of claim 1, wherein the isolation implant region extends through the channel structure to an interface between the channel structure and a substrate.

12. The semiconductor device of claim 1, wherein the isolation implant region extends at least partially into a substrate.

13. The semiconductor device of claim 1, wherein the implanted dopants comprise one or more of nitrogen, hydrogen, helium, zirconium, or oxygen.

14. The semiconductor device of claim 1, wherein the implanted dopants have a peak dopant concentration at a depth in the isolation implant region within about 250 Angstroms or less of a substrate.

15. The semiconductor device of claim 1, wherein the implanted dopants have a peak dopant concentration of at least about 1×10¹⁸ dopants/cm³.

16. The semiconductor device of claim 1, wherein the Group III-nitride semiconductor structure is an N-polar Group III-nitride semiconductor structure.

17. The semiconductor device of claim 1, wherein the Group III-nitride semiconductor structure is on a substrate, the substrate comprising silicon carbide.

18. The semiconductor device of claim 1, wherein the semiconductor device comprises a high electron mobility transistor.

19. A transistor device, comprising:
a substrate;
a Group III-nitride semiconductor structure on the substrate, the Group III-nitride semiconductor structure comprising a first channel structure and a second channel structure that is electrically isolated from the first channel structure;
a source contact on the Group III-nitride semiconductor structure;
a drain contact on the Group III-nitride semiconductor structure; and
wherein the first channel structure and the second channel structure each have a length extending in a first direction that is generally perpendicular to a second direction corresponding to a long dimension of the source contact and a long dimension of the drain contact.

20.-39. (canceled)

40. A method of forming a semiconductor device, comprising:
forming a Group III-nitride semiconductor structure on a substrate;
implanting dopants into the Group III-nitride semiconductor structure to form an isolation implant region in the Group III-nitride semiconductor structure, the isolation implant region separating the Group III-nitride semiconductor structure into a plurality of channel structures, the plurality of channel structures electrically isolated from one another;
forming a first contact on the Group III-nitride semiconductor structure;
forming a second contact on the Group III-nitride semiconductor structure, the second contact spaced apart from the first contact;
wherein each of the plurality of channel structures has a length extending between the first contact and the second contact; and
wherein the isolation implant region extends along a length of one of the plurality of channel structures.

41.-55. (canceled)
